(19) United States
(12) Patent Application Publication
(10) Pub. No.: US 2009/0293930 A1
(43) Pub. Date: Dec. 3, 2009

(54) HIGH EFFICIENCY SKUTTERUDITE TYPE THERMOELECTRIC MATERIALS AND DEVICES

(75) Inventors: Jihui Yang, Lakeshore (CA); Lidong Chen, Shanghai (CN); Wenqing Zhang, Shanghai (CN); Shengqiang Bai, Shanghai (CN); Xun Shi, Troy, MI (US); Ctirad Uher, Ann Arbor, MI (US)

Correspondence Address: General Motors Corporation;c/o REISING, ETHINGTON, BARNES, KISSELLE, P.C., P.O. BOX 4390, TROY, MI, 48099-4390, US

(73) Assignees: GM GLOBAL TECHNOLOGY OPERATIONS, INC.@@SHANGHAI INSTITUTE OF CERAMICS,; CHINESE ACADEMY OF SCIENCES@@THE REGENTS OF THE UNIVERSITY OF MICHIGAN, DETROIT, MI (US)

(21) Appl. No.: 12/396,875

(22) Filed: Mar. 3, 2009

Related U.S. Application Data
(60) Provisional application No. 61/036,715, filed on Mar. 14, 2008.

(51) Int. Cl. H01L 35/12

(52) U.S. Cl. 136/236.1; 252/62.3 T

(57) ABSTRACT

One exemplary embodiment includes a materials and devices comprising a multi-element filled skutterudite type body-centered cubic crystal structure including G_{y}M₄X₁₂, wherein G is at least two elements. The material may include n-type or p-type doping.

This application claims the benefit of United States Provisional Application USSN 61/036,715 filed Mar. 14, 2008.

One or more inventions set forth herein was made under Government Contract No. DE-FC27-04NT42278. The government may have certain rights in one or more inventions described herein.

### TECHNICAL FIELD

The field to which the disclosure generally relates includes thermoelectric materials and devices.

### BACKGROUND

Skutterudite is a cobalt arsenide material which may include variable amounts of nickel and iron substituting for cobalt and has the general formula: (Co, Ni, Fe)As₃.

### SUMMARY OF EXEMPLARY EMBODIMENTS OF THE INVENTION

One exemplary embodiment includes a materials and devices comprising a multi-element filled skutterudite type body-centered cubic crystal structure including G_{y}M₄X₁₂, wherein G is at least two elements. The material may include n-type or p-type doping.

One exemplary embodiment includes a materials and devices comprising a multi-element filled skutterudite type body-centered cubic crystal structure having the formula G_{y}M₄X₁₂, wherein G is at least two elements comprising a rare-earth element and at least one of an alkaline earth element or an alkaline metal element, wherein y is a filling fraction.

Another exemplary embodiment includes a thermoelectric material comprising a partially filled skutterudite-type crystal body structure having the formula G_{y}M₄X₁₂, wherein G comprises two elements comprising a rare-earth element and at least one of an alkaline earth element or an alkaline metal element, wherein y is a filling fraction.

Another exemplary embodiment includes a material including a multi-element filled skutterudite structure having the formula G_{y}M₄X₁₂, where G is at least a first element and a second element, and wherein the first element and second element have different resonance frequencies.

Other exemplary embodiments include materials and devices including n-type and p-type doped multi-element filled skutterudite-type structures including G_{y}M₄X₁₂.

Other exemplary embodiments may include materials and devices including multi-element-filled skutterudites having the formula AₓD_{y}E_{z}M₄X₁₂, where A, D, and E are filler elements of different chemical nature such as rare earths, alkaline earth, and alkaline metal elements, x, y, z are corresponding filling fractions that are subject to filling fraction limits, and M can be Co, Rh, or Ir, with the inclusion of varying amounts of Ni, Pd, Pt and/or Fe, Ru, Os and X can be P, As and/or Sb, with the inclusion of varying amounts of Ge, Sn and/or Se, Te. Such materials may also be doped to provide n-type or p-type thermoelectric materials for a variety of device applications.

Other exemplary embodiments of the invention will become apparent from the detailed description provided hereinafter. It should be understood that the detailed description and specific examples, while disclosing exemplary embodiments of the invention, are intended for purposes of illustration only and are not intended to limit the scope of the invention.

### BRIEF DESCRIPTION OF THE DRAWINGS

Exemplary embodiments of the invention will become more fully understood from the detailed description and the accompanying drawings, wherein:

FIG. 1 is schematic illustration of a skutterudite body-centered cubic crystal structure having the formula G_{y}M_{b}X₁₂ according to one exemplary embodiment of the invention.

FIG. 2 is a graph of ZT versus temperature between 0 K and 1400 K for n- and p-type single-element-filled skutterudites, Bi₂Te₃, PbTe and SiGe alloys.

FIG. 3 is a graph of ZT versus temperature between 0 K and 1400 K for n- and p-type single-element-filled skutterudites, double-filled skutteruidites Ba_{0.08}Yb_{0.09}Co₄Sb₁₂, Bi₂Te₃, PbTe and SiGe alloys.

FIG. 4 is a schematic illustration of a thermoelectric power generator using filled skutterudite materials according to another exemplary embodiment.

### DETAILED DESCRIPTION OF EXEMPLARY EMBODIMENTS

The following description of the embodiment(s) is merely exemplary (illustrative) in nature and is in no way intended to limit the invention, its application, or uses.

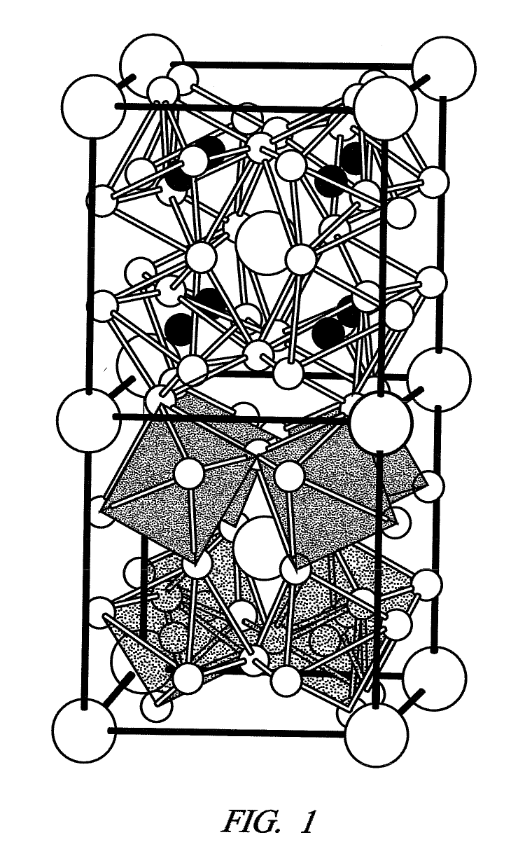

FIG. 1 is a graphic illustration of a skutterudite type body-centered cubic crystal structure having the formula G_{y}M₄X₁₂, wherein G includes at least two elements including a rare-earth element and at least one of an alkaline earth element or an alkaline metal element, according to one exemplary embodiment. Such rare-earth elements may include the lanthanide and actinides series of the periodic table of chemical elements—Lanthanum, Cerium, Praseodymium, Neodymium, Promethium, Samarium, Europium, Gadolinium, Terbium, Dysprosium, Holmium, Erbium, Thulium, Ytterbium, Lutetium, Actinium, Thorium, Protactinium, Uranium, Neptunium, Plutonium, Americium, Curium, Berkelium, Californium, Einsteinium, Fermium, Mendelevium, Nobelium, Lawrencium. Alkaline earth elements include beryllium, magnesium, calcium, strontium, barium and radium. Alkaline metal elements include lithium, sodium, potassium, rubidium, caesium, francium.

The filled skutterudie type structures can be formed by inserting guest atoms interstitially between the large voids in the crystal structure of binary skutterudites compounds. The binary compounds may be filled with elements of different chemical nature such as rare-earth elements in combination with at least one of alkaline earth elements or alkaline metal elements. This results in a broader range of phono scattering for improved thermoelectric figure of merit (ZT) values at elevated temperatures.

The binary compounds may also be filled with at least two elements having different resonance frequencies. For example the elements may be chosen to have different resonance frequencies to increase the rattler induced local vibration modes of the structure over a wider temperature range and so that the material has a reduced thermal conductivity. The resonance frequencies may vary, for example, by 10 cm⁻¹or more.

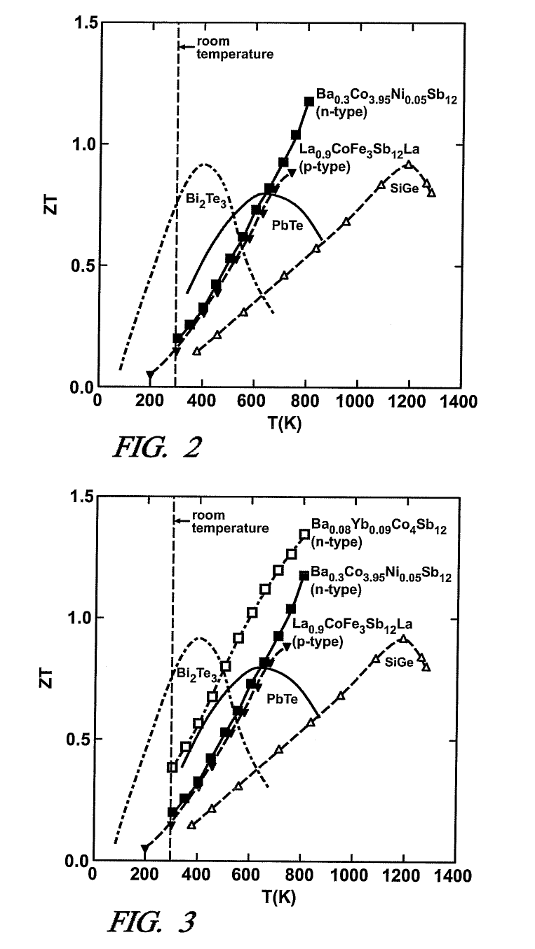

FIG. 3 shows the ZT data for a double-filled skutterudite type structure having the formula Ba_{0.08}Yb_{0.09}Co_{b}Sb₁₂ in addition to those skutterudite structures shown in FIG. 2. The double-filled skutterudite type structure has ZT values larger than those of the single-element-filled skutterudites between room temperature and 800° K. Even larger ZT values may be achieved in multi-element-filled skutterudites having the formula AₓD_{y}E_{z}M₄X₁₂, where A, D, and E are filler elements of different chemical nature such as rare earths, alkaline earth, and alkaline metal elements, x, y, z are corresponding filling fractions that are subject to filling fraction limits, and M can be Co, Rh, or Ir, with the inclusion of varying amounts of Ni, Pd, Pt and/or Fe, Ru, Os, and X can be P, As and/or Sb with the inclusion of varying amounts of Ge, Sn, and/or Se, Te. Such materials may also be doped to provide n-type or p-type thermoelectric materials for a variety of device applications.

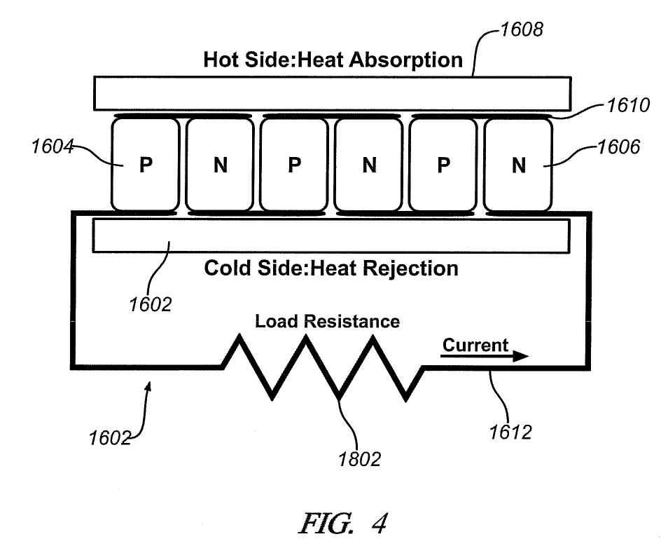

Multi-filled skutterudite type materials may be utilized to make a variety of thermoelectric devices, exemplary embodiments of which are illustrated in FIGS. 4.

FIG. 4 illustrates a thermoelectric power generator 1800 including multi-filled skutterudite-type materials according to one exemplary embodiment. The hot side (plate 1608) is in contact with a heat source of high temperature Tₕ. The cold side (plate 1602) is in contact with a heat sink or heat dumper of low temperature T_{c}<Tₕ. The temperature gradient between the hot side to the cool side makes the carriers in the thermoelectric pieces 1604 and 1606 move away from the hot side and towards the cool side. An electric current is thus generated in each thermoelectric element in a direction from the n-type piece 1606 to the p-type piece 1604. The electrical power generation is increased by increasing the temperature difference and by using multi-filled skutterudite materials of large ZT values.

The above description of embodiments of the invention is merely exemplary in nature and, thus, variations thereof are not to be regarded as a departure from the spirit and scope of the invention.

What is claimed is:

1. A thermoelectric material comprising a skutterudite type body-centered cubic crystal structure comprising G_{y}M₄X₁₂, wherein G is a multi-element filling at least some of the crystallographic voids of the skutterudite type structure, and wherein G comprises a rare-earth element and at least one of an alkaline earth element or an alkaline metal element, and y is a filling fraction.

2. A material as set forth in claim 1 further comprising p-type dopants.

3. A material as set forth in claim 1 further comprising n-type dopants.

4. A material as set forth in claim 1 having the formula Ba_{0.08}Yb_{0.09}Co₄Sb₁₂.

5. A thermoelectric material comprising a skutterudite type body-centered cubic crystal structure comprising G_{y}M₄X₁₂, wherein G is a multi-element filling at least some of the crystallographic voids of the skutterudite type structure, and wherein G comprises at least a first and second element, and wherein the first and second element have difference resonance frequencies.

6. A material as set forth in claim 5 further comprising p-type dopants.

7. A material as set forth in claim 5 further comprising n-type dopants.

8. A product comprising a material comprising skutterudite type body-centered cubic crystal structure comprising G_{y}M₄X₁₂, wherein G is a multi-element filling at least some of the crystallographic voids of the skutterudite type structure, and wherein G comprises at least a first and second element, and wherein the second element is select so that the material has a lower thermal conductivity than a material wherein G is only the first element.

9. A product as set forth in claim 8 wherein the material further comprises p-type dopants.

10. A material as set forth in claim 8 wherein the material further comprises n-type dopants.

11. A thermoelectric material comprising AₓD_{y}E_{z}M₄X₁₂, wherein A, D and E are filler elements of different chemical nature, x, y, z are filling fractions, M is at least one of Co, Rh or Ir, and X is at least one of S_{b}, P or As.

12. A material as set forth in claim 1 further comprising p-type dopants.

13. A material as set forth in claim 1 further comprising n-type dopants.

14. A thermoelectric device comprising:
a p-type thermoelectric material comprising AₓD_{y}E_{z}M₄X₁₂, wherein A, D and E are filler elements of different chemical nature, x, y, z are filling fractions, M is at least one of Co, Rh or Ir, and X is at least one of S_{b}, P or As,
and a p-type thermoelectric material comprising AₓD_{y}E_{z}M₄X₁₂, wherein A, D and E are filler elements of different chemical nature, x, y, z are filling fractions, M is at least one of Co, Rh or Ir, and X is at least one of S_{b}, P or As.

15. A thermoelectric device comprising:
a first thermoelectric multi-filled skutterudite material of p-type formed from a thermoelectric material comprising G_{y}M₄X₁₂, where G comprises a rare-earth element and at least one of an alkaline earth element and an alkaline metal element, and wherein y is a filling fraction, and a second thermoelectric multi-filled skutterudite type material of the n-type derived from a material comprising G_{y}M₄X₁₂, where y is a filling fraction.
